(19) United States
(12) Patent Application Publication
(10) Pub. No.: US 2026/0173793 A1
(43) Pub. Date: Jun. 18, 2026

(54) COATING DEVICE, COATING METHOD OF DISPLAY DEVICE AND ELECTRONIC DEVICE MANUFACTURED USING THE COATING DEVICE

(71) Applicant: Samsung Display Co., Ltd., Yongin-Si (KR)

(72) Inventors: Sung Kook LEE, Yongin-si (KR); Jung Kyu LEE, Yongin-si (KR)

(21) Appl. No.: 19/312,307

(22) Filed: Aug. 28, 2025

(30) Foreign Application Priority Data
Dec. 17, 2024 (KR) 10-2024-0188123

(51) Int. Cl. H01L 21/67; H01L 21/56

(52) U.S. Cl. CPC H10P 72/0441; H10W 74/01

(57) ABSTRACT

A coating device includes a main jig supporting a display device, an auxiliary jig located on the main jig and extending from an upper surface of the main jig, and supporting an edge of the display device, and a coating nozzle supplying a coating solution to the display device.

### CROSS-REFERENCE TO RELATED APPLICATION

This application claims priority under 35 U.S.C. § 119 to Korean Patent Application No. 10-2024-0188123 filed on Dec. 17, 2024, in the Korean Intellectual Property Office, the entire contents of which are herein incorporated by reference.

### BACKGROUND

### 1. Technical Field

The present disclosure relates to a coating device, a coating method of a display device, and an electronic device manufactured using the coating device.

### 2. Description of the Related Art

Mobile electronic devices or large electronic devices such as televisions are equipped with a display panel in which pixels are arranged to display an image, and a cover member to protect the display panel. The display panel may include a liquid display panel or an organic light emitting display panel.

Various coating layers may be formed on the cover member to improve durability of the cover member and prevent the user's fingerprint from adhering to the cover member. The coating layers may be formed on the top surface of the cover member using a coating device.

### SUMMARY

Aspects of the present disclosure provide a coating device capable of improving a surface quality of a coating layer formed on top of the cover member, a coating method of a display device, and an electronic device manufactured using the coating device.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an embodiment of the present disclosure, a coating device includes a main jig supporting a display device, an auxiliary jig located on the main jig and extending from an upper surface of the main jig, and supporting an edge of the display device, and a coating nozzle supplying a coating solution to the display device.

The display device may include a display panel, a panel lower member located under the display panel, and a cover member located on the display panel, and having a wider width than the display panel. The panel lower member may be supported by the main jig, and an edge of the cover member may be supported by the auxiliary jig.

The coating nozzle may supply the coating solution to an upper surface of the cover member.

The auxiliary jig may be provided in plural forms, and the plurality of auxiliary jigs may be arranged to surround the display panel and the panel lower member.

The plurality of auxiliary jigs may be arranged to be spaced apart from the display panel and the panel lower member along a first direction.

The plurality of auxiliary jigs may be formed to extend outside the edge of the cover member so that an entire edge of the cover member is supported by the plurality of auxiliary jigs.

The coating device may further include a main adsorption portion located in the main jig, and adsorbing the panel lower member onto the main jig, a main vacuum generator applying a first vacuum pressure to the main adsorption portion, an auxiliary adsorption portion located in the auxiliary jig, and adsorbing the edge of the cover member onto the auxiliary jig, and an auxiliary vacuum generator applying a second vacuum pressure to the auxiliary adsorption portion.

A plurality of main suction holes may be formed in an upper surface of the main adsorption portion in contact with the panel lower member, and a plurality of auxiliary suction holes may be formed in an upper surface of the auxiliary adsorption portion in contact with the edge of the cover member.

The coating device may further include a main connecting portion connecting the main adsorption portion to the main vacuum generator, and an auxiliary connecting portion connecting the auxiliary adsorption portion to the auxiliary vacuum generator.

The main vacuum generator and the auxiliary vacuum generator may be located inside the main jig, and the main vacuum generator and the auxiliary vacuum generator may be operated independently from each other.

When the coating nozzle supplies the coating solution to the cover member, the main vacuum generator and the auxiliary vacuum generator may be operated simultaneously, and when the coating solution supplied to the cover member is cured, only the auxiliary vacuum generator may be operated.

According to an embodiment of the present disclosure, a coating method includes placing a panel lower member of a display device on a main jig and placing an edge of a cover member of the display device on an auxiliary jig, adsorbing the panel lower member using the main jig and adsorbing the edge of the cover member using the auxiliary jig, supplying a coating solution to an upper surface of the cover member through a coating nozzle, and forming a coating layer by curing the coating solution supplied to the upper surface of the cover member.

The auxiliary jig may include an auxiliary adsorption portion adsorbing the edge of the cover member, and the main jig may include a main adsorption portion adsorbing the panel lower member, a main vacuum generator applying a first vacuum pressure to the main adsorption portion, and an auxiliary vacuum generator applying a second vacuum pressure to the auxiliary adsorption portion.

In the process of adsorbing the panel lower member using the main jig and adsorbing the edge of the cover member using the auxiliary jig, the main vacuum generator may apply the first vacuum pressure to the main adsorption portion to adsorb the panel lower member by the main adsorption portion, and the auxiliary vacuum generator may apply the second vacuum pressure to the auxiliary adsorption portion to adsorb the edge of the cover member by the auxiliary adsorption portion.

In the process of supplying the coating solution to the upper surface of the cover member by the coating nozzle, the main adsorption portion may adsorb the panel lower member and the auxiliary adsorption portion may adsorb the edge of the cover member.

In the process of forming the coating layer by curing the coating solution supplied to the upper surface of the cover member, the auxiliary vacuum generator may be operated so that the auxiliary adsorption portions adsorbs the edge of the cover.

The coating method may further include cutting the edge of the cover member by a laser cutter.

According to an embodiment of the present disclosure, an electronic device includes a display device manufactured using a coating device. The coating device comprises a main jig supporting a panel lower member of a display device, an auxiliary jig located on the main jig and extending from an upper surface of the main jig, and supporting an edge of a cover member of the display device, and a coating nozzle supplying a coating solution to the cover member of the display device.

The electronic device may further include a main adsorption portion located in the main jig, and adsorbing the panel lower member onto the main jig, a main vacuum generator applying a first vacuum pressure to the main adsorption portion, an auxiliary adsorption portion located in the auxiliary jig, and adsorbing the edge of the cover member onto the auxiliary jig, and an auxiliary vacuum generator applying a second vacuum pressure to the auxiliary adsorption portion.

When the coating nozzle supplies the coating solution to the cover member, the main vacuum generator and the auxiliary vacuum generator may be operated simultaneously, and when the coating solution supplied to the cover member is cured, only the auxiliary vacuum generator may be operated.

In accordance with the coating device, the coating method of the display device using the coating device, and the electronic device manufactured using the coating device according to the present disclosure, as an edge of a cover member is adsorbed and supported by an auxiliary jig during the process of coating the coating layer on the upper surface of the cover member, the surface quality of the coating layer may be improved by preventing the coating layer from bending.

The effects according to the embodiments of the present disclosure are not limited to those mentioned above and more various effects are included in the following description of the present disclosure.

### BRIEF DESCRIPTION OF THE DRAWINGS

The above and other aspects and features of the present disclosure will become apparent and more readily appreciated from the following description of the embodiment, taken in conjunction with the accompanying drawings.

FIG. 1 is a plan view showing a coating device according to an embodiment of the present disclosure.

FIG. 2 is a cross-sectional view taken along a line A-A′ of FIG. 1.

FIG. 3 is a cross-sectional view schematically illustrating a display device of an embodiment.

FIG. 4 is a cross-sectional view schematically illustrating a display panel of FIG. 3.

FIG. 5 is a plan view illustrating a state where a display panel is mounted on a coating device of FIG. 1.

FIG. 6 is a cross-sectional view taken along a line B-B′ of FIG. 5.

FIG. 7 is a diagram illustrating a state where a display device is mounted on a main jig and an auxiliary jig in a coating method of a display device according to an embodiment of the present disclosure.

FIG. 8 is a diagram illustrating a state where coating solution is supplied from a coating nozzle to a cover member of a display device, in a state shown in FIG. 7.

FIG. 9 is a diagram illustrating a state where coating solution is supplied to an upper surface of the cover member.

FIG. 10 is a diagram illustrating a state where coating solution supplied to a cover member is being cured.

FIG. 11 is a diagram illustrating a state where a laser cutter cuts an edge of a cover member, in a state shown in FIG. 10.

FIG. 12 is a block diagram of an electronic device according to an embodiment.

FIG. 13 are schematic diagrams of electronic devices according to various embodiments.

### DETAILED DESCRIPTION OF THE EMBODIMENTS

Advantages and features of the present disclosure and methods to achieve them will become apparent from the following descriptions of embodiments with reference to the accompanying drawings. However, the present disclosure is not limited to the embodiments disclosed herein but may be implemented in various different ways. These embodiments are merely provided to ensure the full disclosure of the present inventive concept and to completely convey the scope of the present disclosure to those skilled in the art. It is to be noted that the scope of the present disclosure is defined only by the claims.

As used herein, a phrase “an element A on an element B” not only refers to that the element A may be disposed directly on the element B but also refers to that the element A may be disposed indirectly on the element B with an interposed element C therebetween. Like reference numerals denote like elements throughout the descriptions. The figures, dimensions, ratios, angles, numbers of elements given in the drawings are merely illustrative and are not limiting.

Although the terms “first”, “second”, etc. may be used herein to describe various elements, these elements should not be limited by these terms. These terms may be used to distinguish one element from another element. Accordingly, as used herein, a first element may be referred to as a second element without departing from the technical scope of the present disclosure.

Each of the features of the various embodiments of the present disclosure may be partially or entirely combined with each other and technically interwork with each other in various ways. Each embodiment may be implemented independently from each other or may be implemented together in association with each other.

Hereinafter, embodiments of the present disclosure will be described in detail with reference to the accompanying drawings.

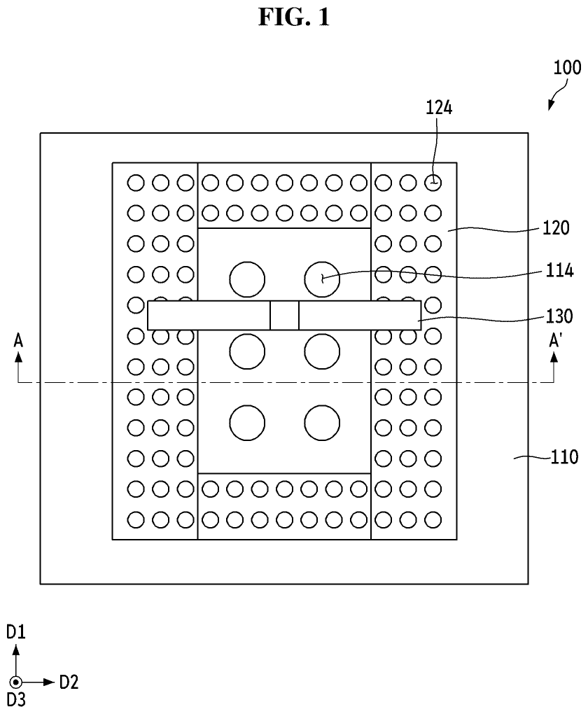

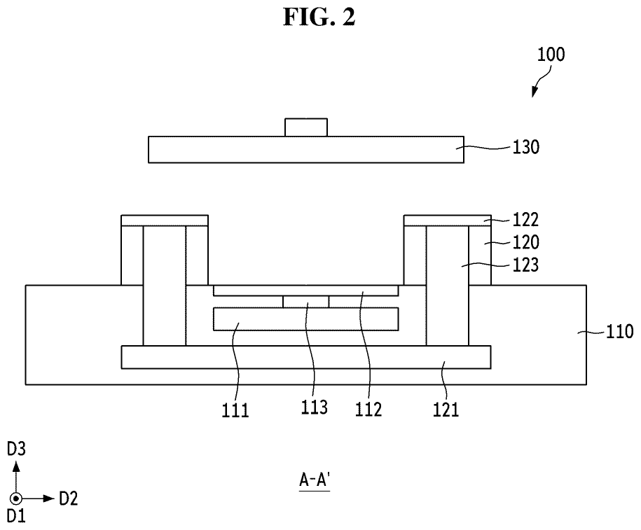

FIG. 1 is a plan view showing a coating device according to an embodiment of the present disclosure. FIG. 2 is a cross-sectional view taken along a line A-A′ of FIG. 1.

Referring to FIGS. 1 and 2, a coating device 100 according to an embodiment of the present disclosure may include a main jig 110, an auxiliary jig 120, and a coating nozzle 130.

The main jig 110 may support various components of the coating device 100 and a display device. The main jig 110 may extend in a first direction D1 and a second direction D2, and may be formed to have a thickness in a third direction D3. The planar shape of the main jig 110 may be formed in a rectangular shape, but the present disclosure is not limited thereto. The main jig 110 may follow the planar shape of the display device mounted on the main jig 110. The planar size of the main jig 110 may be larger than the planar size of the display device mounted on the main jig 110. Inside the main jig 110, an arrangement space may be formed to accommodate a main vacuum generator 111, a main adsorption portion 112, a main connection portion 113, an auxiliary vacuum generator 121, and an auxiliary connection portion 123, which will be described later.

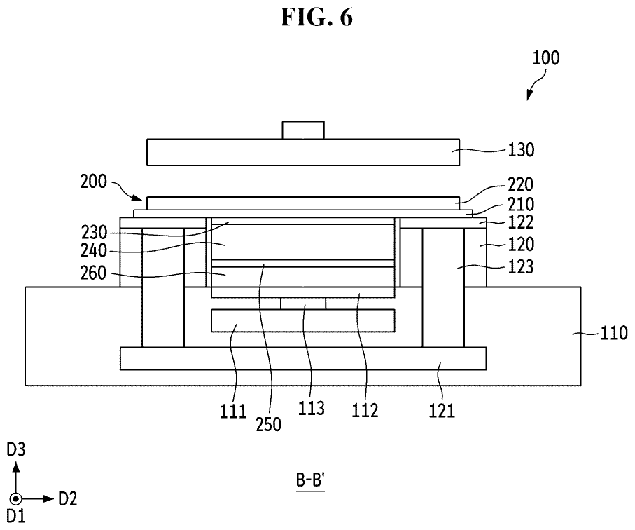

The auxiliary jig 120 may be placed on the main jig 110. The auxiliary jig 120 may extend from an upper surface of the main jig 110 in the third direction D3. A plurality of auxiliary jigs 120 may be provided, and the plurality of auxiliary jigs 120 may be arranged on the upper surface of the main jig 110 and surround the display device mounted on top of the main jig 110. The auxiliary jig 120 may support an edge of the display device mounted on top of the main jig 110. For example, the auxiliary jig 120 may be formed to extend outside the display device, e.g., an edge of a cover member 210 (see FIG. 6 below), so that the entire edge of the cover member 210 is supported by the auxiliary jig 120. Inside the auxiliary jig 120, an arrangement space may be formed to accommodate a portion of the auxiliary connection portion 123 and an auxiliary absorption portion 122 to be described later.

The coating nozzle 130 may be placed above the main jig 110 and the auxiliary jig 120. The coating nozzle 130 may be moved in the first direction D1 above the main jig 110 and the auxiliary jig 120. The coating nozzle 130 may supply a coating solution to the display device mounted on top of the main jig 110 while moving in the first direction D1. The coating nozzle 130 may be provided as a slit nozzle.

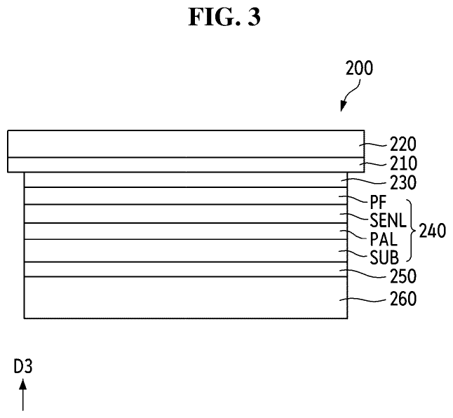

FIG. 3 is a cross-sectional view schematically illustrating a display device of an embodiment.

Referring to FIG. 3, a display device 200 according to an embodiment may include a cover member 210, a coating layer 220, a first adhesive layer 230, a display panel 240, a second adhesive layer 250, and a panel lower member 260.

The cover member 210 may include a material with high light transmittance. The cover member 210 may include a polymer resin such as polyimide or glass. The cover member 210 may be disposed on a polarizing film PF of the display panel 240, which will be described later.

The coating layer 220 may be formed on top of the cover member 210. The coating layer 220 may improve durability of the cover member 210 and prevent the user's fingerprint from adhering to the cover member 210. The coating layer 220 may be formed by curing the coating solution supplied from the coating nozzle 130 of the coating device 100.

The first adhesive layer 230 is located between the cover member 210 and the polarizing film PF of the display panel 240 to attach the cover member 210 to the polarizing film PF of the display panel 240. The first adhesive layer 230 may include an adhesive member such as an optically clear adhesive (OCA) film or a pressure sensitive adhesive (PSA).

The display panel 240 may be located below the cover member 210. The display panel 240 may have a rectangular planar shape with a pair of long sides and a pair of short sides. In the display panel 240, a corner where a pair of long sides and a pair of short sides meet may be formed at a right angle or may be rounded to have a predetermined curvature. The display panel 240 may have a quadrilateral shape other than a rectangle, a polygon other than a quadrilateral shape, a circular shape, an oval shape, or an irregular planar shape.

The display panel 240 may include a display area in which a plurality of emission areas that emit light are arranged and a non-display area located around the display area. The non-display area may surround at least a portion of the display area. A plurality of display pads may be disposed in a non-display area at one edge of the display panel 240.

The display panel 240 may include a substrate SUB, a display unit PAL, a sensor unit SENL, and the polarizing film PF.

The substrate SUB may include an insulating material such as glass, quartz, or polymer resin. The substrate SUB may be a rigid substrate or a flexible substrate that can be bent, folded, or rolled.

The display unit PAL may be located on the substrate SUB. The display unit PAL may be a layer including the plurality of emission areas that emit light. The display unit PAL may include a buffer film, a thin-film transistor layer in which thin-film transistors are disposed, a light-emitting element layer that emits light, and an encapsulating layer protecting the light-emitting element layer.

The sensor unit SENL may be disposed on the display unit PAL. The sensor unit SENL may include sensor electrodes and may sense an event when a user touches the sensor unit SENL.

The polarizing film PF may be located on the sensor unit SENL. The polarizing film PF can prevent the deterioration of image visibility of the display panel 240 due to reflection of external light. The polarizing film PF may include a linear polarizer and a phase retardation film such as a ¼ (quarter-wave) plate. The phase retardation film may be located on the sensor unit SENL, and the linear polarizer may be located on the phase retardation film. The cover member 210 may be located on the polarizing film PF.

The second adhesive layer 250 may be located between the substrate SUB of the display panel 240 and the panel lower member 260 to attach the substrate SUB of the display panel 240 to the panel lower member 260. The second adhesive layer 250 may include an adhesive member such as an optically clear adhesive (OCA) film or a pressure sensitive adhesive (PSA).

The panel lower member 260 may be located under the substrate SUB. The panel lower member 260 may include at least one of a light-absorbing member for absorbing light incident from outside, a buffer member for absorbing external impact, and a heat dissipating member for efficiently discharging heat from the display panel 240.

The light-absorbing member may be located under the substrate SUB. The light-absorbing member blocks the transmission of light to prevent the elements, such as a driving circuit board (not illustrated), disposed under the substrate SUB from being visible from outside of the display panel 240. The light-absorbing member may include a light-absorbing material such as a black pigment and a black dye.

The buffer member may be located under the light-absorbing member. The buffer member absorbs an external impact to prevent the display panel 240 from being damaged. The buffer member may be a single layer or multiple layers. For example, the buffer member may be formed of a polymer resin such as polyurethane, polycarbonate, polypropylene and polyethylene, or may be formed of a material having elasticity such as a rubber and a sponge obtained by foaming a urethane-based material or an acrylic-based material.

The heat dissipating member may be located under the buffer member. The heat dissipating member may include a first heat dissipation layer including graphite or carbon nanotubes, and a second heat dissipation layer including a thin metal film such as copper, nickel, ferrite and silver, which can block electromagnetic waves and have high thermal conductivity.

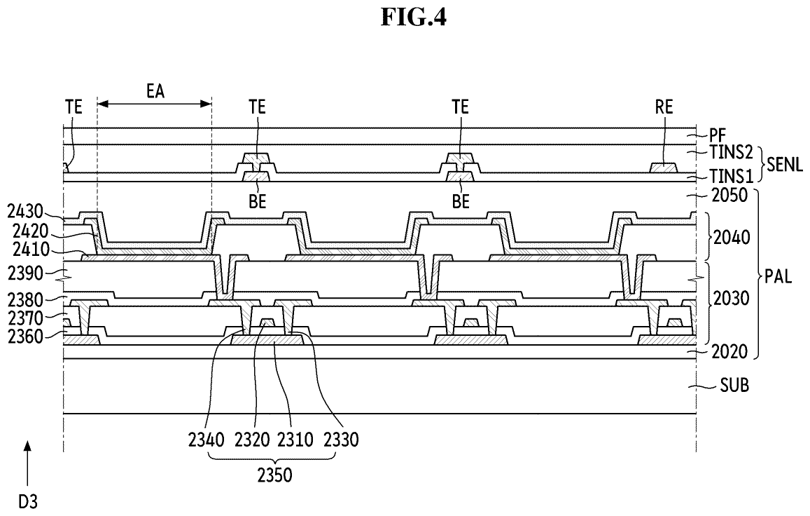

FIG. 4 is a cross-sectional view schematically illustrating a display panel of FIG. 3.

Referring to FIG. 4, the display unit PAL may include a buffer film 2020, a thin-film transistor layer 2030, a light-emitting element layer 2040, and an encapsulation layer 2050.

The buffer film 2020 may be formed on the substrate SUB. The buffer film 2020 may be formed on the substrate SUB to protect thin-film transistors 2350 and light-emitting elements from moisture through the substrate SUB which is susceptible to moisture permeation. The buffer film 2020 may include multiple inorganic films alternately stacked. For example, the buffer film 2020 may include in which one or more inorganic films such as a silicon oxide film (SiOx), a silicon nitride film (SiNx), and a silicon oxynitride film (SiON) are alternately stacked. The buffer film 2020 may be omitted.

The thin-film transistor layer 2030 may be disposed on the buffer film 2020. The thin-film transistor layer 2030 includes the thin-film transistors 2350, a gate insulating film 2360, an interlayer insulating film 2370, a protective film 2380, and an organic film 2390.

Each of the thin-film transistors 2350 includes an active layer 2310, a gate electrode 2320, a source electrode 2330, and a drain electrode 2340. FIG. 4 illustrates an embodiment where the thin-film transistor 2350 is formed in a top gate manner in which the gate electrode 2320 is located on top of the active layer 2310, but it should be noted that the present disclosure is not limited thereto. That is, the thin-film transistors 2350 may be formed in a bottom gate manner in which the gate electrode 2320 is located under the active layer 2310, or formed in a double gate manner in which dual gate electrodes are located on both top and bottom of the active layer 2310.

The active layer 2310 is formed on the buffer film 2020. The active layer 2310 may include a silicon-based semiconductor material or an oxide-based semiconductor material. For example, the active layer 2310 may include a poly silicon, an amorphous silicon, or an oxide semiconductor. A light blocking layer for blocking external light incident on the active layer 2310 may be formed between the buffer film 2020 and the active layer 2310.

The gate insulating film 2360 may be formed on the active layer 2310. The gate insulating film 2360 may include an inorganic film, for example, a silicon oxide film (SiOx), a silicon nitride film (SiNx), or a multiple film thereof.

The gate electrode 2320 may be formed on the gate insulating film 2360. The gate electrode 2320 and a gate line may be a single layer or multiple layers including any one of molybdenum (Mo), aluminum (Al), chromium (Cr), gold (Au), titanium (Ti), nickel (Ni), neodymium (Nd) and copper (Cu), or an alloy thereof.

The interlayer insulating film 2370 may be formed on the gate electrode 2320 and the gate line. The interlayer insulating film 2370 may include an inorganic film, for example, a silicon oxide film (SiOx), a silicon nitride film (SiNx), or a multiple film thereof.

The source electrode 2330 and the drain electrode 2340 may be formed on the interlayer insulating film 2370. Each of the source electrode 2330 and the drain electrode 2340 may be connected to the active layer 2310 through a contact hole extending through the gate insulating film 2360 and the interlayer insulating film 2370. The source electrode 2330 and the drain electrode 2340 may be a single layer or multiple layers including any one of molybdenum (Mo), aluminum (Al), chromium (Cr), gold (Au), titanium (Ti), nickel (Ni), neodymium (Nd) and copper (Cu), or an alloy thereof.

The protective film 2380 for insulating the thin-film transistors 2350 may be formed on the source electrode 2330 and the drain electrode 2340. The protective film 2380 may include an inorganic film, for example, a silicon oxide film (SiOx), a silicon nitride film (SiNx), or a multiple film thereof.

The organic film 2390 for planarizing a step due to the thin-film transistor 2350 may be formed on the protective film 2380. The organic film 2390 may include an organic film such as acryl resin, epoxy resin, phenolic resin, polyamide resin, polyimide resin and the like.

The light-emitting element layer 2040 is formed on the thin-film transistor layer 2030. The light-emitting element layer 2040 includes the light-emitting elements and a bank.

The light-emitting elements and the bank are formed on the organic film 2390. The light-emitting element is exemplified as an organic light-emitting element including an anode electrode 2410, a light-emitting layer 2420, and a cathode electrode 2430.

The anode electrode 2410 may be formed on the organic film 2390. The anode electrode 2410 may be connected to the drain electrode 2340 of the thin-film transistor 2350 through a contact hole extending through the protective film 2380 and the organic film 2390.

The bank may cover the edge of the anode electrode 2410 on the organic film 2390 and partition emission areas EA of pixels. That is, the bank serves to define the emission areas EA of pixels. Each of the pixels represents a region where the anode electrode 2410, the light-emitting layer 2420, and the cathode electrode 2430 are sequentially stacked, and where holes from the anode electrode 2410 and electrons from the cathode electrode 2430 are combined with each other in the light-emitting layer 2420 to emit light.

The light-emitting layer 2420 is formed on the anode electrode 2410 and the bank. The light-emitting layer 2420 may be an organic light-emitting layer. The light-emitting layer 2420 may emit one of red light, green light and blue light. However, the present disclosure is not limited thereto. For example, the light-emitting layer 2420 may be a white light-emitting layer that emits white light. In this case, the light-emitting layer 2420 may have a structure in which a red light-emitting layer, a green light-emitting layer, and a blue light-emitting layer are stacked, and may be a common layer formed commonly to the pixels. In this case, the display panel 240 may further include a separate color filter for displaying a red, green or blue color.

The light-emitting layer 2420 may include a hole transporting layer, a light-emitting layer, and an electron transporting layer. In addition, the light-emitting layer 2420 may be formed in a tandem structure including two or more stacks, in which case a charge generating layer may be formed between the stacks.

The cathode electrode 2430 is formed on the light-emitting layer 2420. The cathode electrode 2430 may be formed to cover the light-emitting layer 2420. The cathode electrode 2430 may be a common layer formed commonly to the pixels.

In a case where the light-emitting element layer 2040 is formed in a top emission manner in which light is emitted upward, the anode electrode 2410 may include a metal material having high reflectivity and have a stacked structure (Ti/Al/Ti) of aluminum and titanium, a stacked structure (ITO/Al/ITO) of aluminum and ITO, an APC alloy, or a stacked structure (ITO/APC/ITO) of an APC alloy and ITO. The APC alloy is an alloy of silver (Ag), palladium (Pd) and copper (Cu). Further, the cathode electrode 2430 may include a transparent conductive material (TCO) such as ITO or IZO that can transmit light or a semi-transmissive conductive material such as magnesium (Mg), silver (Ag), or an alloy of magnesium (Mg) and silver (Ag). In a case where the cathode electrode 2430 includes a semi-transmissive conductive material, the light emission efficiency may be increased due to a micro-cavity effect.

In a case where the light-emitting element 2040 is formed in a bottom emission manner in which light is emitted downward, the anode electrode 2410 may include a transparent conductive material (TCO) such as ITO or IZO or a semi-transmissive conductive material such as magnesium (Mg), silver (Ag), or an alloy of magnesium (Mg) and silver (Ag). The cathode electrode 2430 may include a metal material, having high reflectivity, such as a stacked structure (Ti/Al/Ti) of aluminum (Al) and titanium (Ti), a stacked structure (ITO/Al/ITO) of Al and ITO, an APC alloy, a stacked structure (ITO/APC/ITO) of an APC alloy and ITO, or the like. In a case where the anode electrode 2410 includes a semi-transmissive conductive material, the light emission efficiency may be increased due to a micro-cavity effect.

The encapsulation layer 2050 is formed on the light-emitting element layer 2040. The encapsulation layer 2050 serves to prevent air or moisture from permeating the light-emitting layer 2420 and the cathode electrode 2430. To this end, the encapsulation layer 2050 may further include at least one inorganic film. The inorganic film may include silicon nitride, aluminum nitride, zirconium nitride, titanium nitride, hafnium nitride, tantalum nitride, silicon oxide, aluminum oxide, or titanium oxide. In addition, the encapsulation layer 2050 may further include at least one organic film. The organic film may have a thickness sufficient to prevent particles from penetrating the encapsulation layer 2050 and entering into the light-emitting layer 2420 and the cathode electrode 2430. The organic film may include at least one of epoxy, acrylate, and urethane acrylate.

The sensor unit SENL may be formed on the encapsulation layer 2050. In case in which the sensor unit SENL is formed directly on the encapsulation layer 2050, the thickness of the display device 200 can be reduced, compared with a display device in which a separate touch panel is attached on the encapsulation layer 2050.

The sensor unit SENL may include sensor electrodes for sensing a user's touch by a capacitive manner, and touch lines connecting the pads and the sensor electrodes. For example, the sensor unit SENL can sense a user's touch by self-capacitance sensing or mutual capacitance sensing. In the example shown in FIG. 4, the sensor unit SENL includes two layers including driving electrodes TE, sensing electrodes RE, and bridges BE connecting adjacent driving electrodes TE.

The bridges BE may be formed on the encapsulation layer 2050. The bridges BE may include, but is not limited to, a stack structure of aluminum and titanium (Ti/Al/Ti), a stack structure of aluminum and ITO (ITO/Al/ITO), an APC alloy or a stack structure of APC alloy and ITO (ITO/APC/ITO). For example, the bridges BE may include a single layer of molybdenum (Mo), titanium (Ti), copper (Cu), aluminum (Al) or ITO.

A first sensing insulating film TINS1 is formed over the bridges BE. The first sensing insulating film TINS1 may include an inorganic film, for example, a silicon nitride layer, a silicon oxynitride layer, a silicon oxide layer, a titanium oxide layer, or an aluminum oxide layer.

The driving electrodes TE and the sensing electrodes RE may be formed on the first sensing insulating film TINS1. The driving electrode TE and the sensing electrode RE may include, but is not limited to, a stack structure of aluminum and titanium (Ti/Al/Ti), a stack structure of aluminum and ITO (ITO/Al/ITO), an APC alloy or a stack structure of APC alloy and ITO (ITO/APC/ITO). For example, the driving electrodes TE and the sensing electrodes RE may include a single layer of molybdenum (Mo), titanium (Ti), copper (Cu), aluminum (Al) or ITO.

Contact holes may be formed in the first sensing insulating film TINS1 which penetrate the first sensing insulating film TINS1 to expose the bridges BE. The driving electrodes TE may be connected to the bridges BE through the contact holes.

A second sensing insulating film TINS2 is formed on the driving electrodes TE and the sensing electrodes RE. The second sensing insulating film TINS2 may provide a flat surface over the driving electrodes TE, the sensing electrodes RE and the bridges BE which have different heights. The second sensing insulating film TINS2 may include an organic film such as an acryl resin, an epoxy resin, a phenolic resin, a polyamide resin and a polyimide resin.

The bridges BE connecting the adjacent driving electrodes TE may be disposed on the encapsulation layer 2050, and the driving electrodes TE and the sensing electrodes RE may be disposed on the first sensing insulating film TINS1. Therefore, the driving electrodes TE and the sensing electrodes RE may be electrically separated from each other at their intersections, while the sensing electrodes RE may be electrically connected with one another in a direction, and the driving electrodes TE may be electrically connected with one another in another direction.

The polarizing film PF may be disposed on the second sensing insulating film TINS2 and can prevent the deterioration of image visibility of the display panel 240 due to reflection of external light.

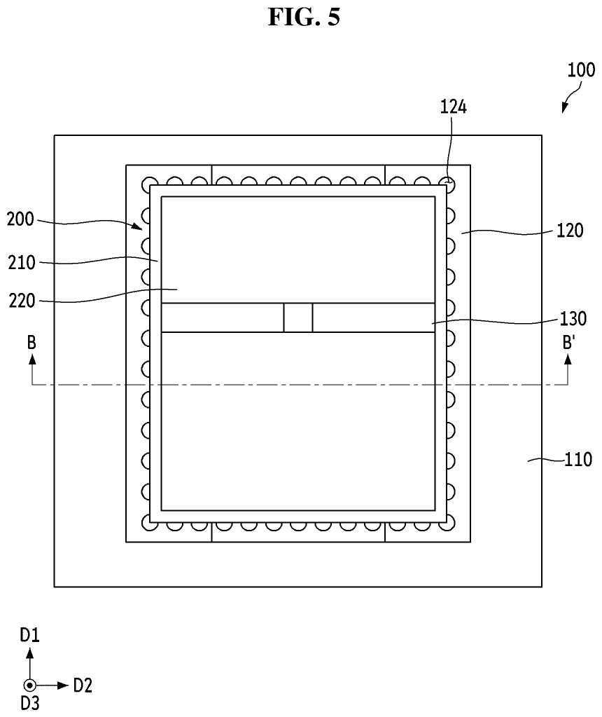

FIG. 5 is a plan view illustrating a state where a display panel is mounted on a coating device of FIG. 1. FIG. 6 is a cross-sectional view taken along a line B-B′ of FIG. 5.

The display device 200 may be supported by the main jig 110 and the auxiliary jig 120. The cover member 210 of the display device 200 may have a width greater than the display panel 240 and the panel lower member 260 so that the edge of the cover member 210 extends to outer side of the display panel 240 and the panel lower member 260. The panel lower member 260 of the display device 200 may be mounted on the upper surface of the main jig 110 to be supported by the main jig 110, and the edge of the cover member 210 of the display device 200 may be mounted on the upper surface of the auxiliary jig 120 to be supported by the auxiliary jig 120.

The coating nozzle 130 may supply the coating solution to an upper surface of the cover member 210 as it moves in the first direction D1 from an upper side of the display device 200.

The plurality of auxiliary jigs 120 may be arranged to surround the display panel 240 and the panel lower member 260. The upper ends of the plurality of auxiliary jigs 120 may be located on the same virtual line as the upper surface of the first adhesive layer 230. Accordingly, the upper surfaces of the plurality of auxiliary jigs 120 may be in contact with a lower surface of the cover member 210.

The plurality of auxiliary jigs 120 may be arranged to be spaced apart from the display panel 240 and the panel lower member 260 at a predetermined distance. The plurality of auxiliary jigs 120 may extend outside the edge of the cover member 210 along the second direction D2. Accordingly, all edges of the cover member 210 may be supported by the plurality of auxiliary jigs 120.

The coating device 100 according to an embodiment of the present disclosure may further include a main vacuum generator 111, a main adsorption portion 112, a main connection portion 113, a main suction hole 114 (see FIG. 1), an auxiliary vacuum generator 121, an auxiliary adsorption portion 122, an auxiliary connection portion 123, and an auxiliary suction hole 124.

The main vacuum generator 111 may be placed inside the main jig 110. The main vacuum generator 111 may apply vacuum pressure to the main adsorption portion 112. The main vacuum generator 111 may be operated by receiving power from a separate power supplier (not illustrated), and the separate power supplier (not illustrated) may be placed inside or outside the main jig 110 and connected to the main vacuum generator 111 through a power line (not illustrated). The main vacuum generator 111 may include a vacuum pump that generates vacuum pressure. The main vacuum generator 111 may operate only when the coating nozzle 130 supplies the coating solution to the cover member 210. The main vacuum generator 111 may operate independently from the auxiliary vacuum generator 121.

The main adsorption portion 112 may be disposed in the main jig 110, and may adsorb the panel lower member 260 onto the main jig 110. The main adsorption portion 112 may be disposed inside the main jig 110 and contact the upper surface of the main jig 110, and may be located directly beneath the panel lower member 260. The main adsorption portion 112 may adsorb the panel lower member 260 using vacuum pressure from the main vacuum generator 111.

The main connection portion 113 may connect the main vacuum generator 111 and the main adsorption portion 112 to each other inside the main jig 110. The main connection portion 113 may provide a pathway through which the vacuum pressure generated from the main vacuum generator 111 is applied to the main adsorption portion 112.

A plurality of main suction holes 114 (see FIG. 1) may be provided, and the plurality of main suction holes 114 may be arranged along the first direction D1 and the second direction D2 on the upper surface of the main adsorption portion 112. The plurality of main suction holes 114 may be formed to penetrate the upper surface of the main jig 110 so that vacuum pressure applied to the main adsorption portion 112 may act directly on the panel lower member 260. In other words, a suction force may be generated from the plurality of main suction holes 114 to cause the panel lower member 260 to be adsorbed by the main adsorption portion 112.

The auxiliary vacuum generator 121 may be located inside the main jig 110. The auxiliary vacuum generator 121 may apply vacuum pressure to the auxiliary adsorption portion 122. The auxiliary vacuum generator 121 may receive power provided from a separate power supplier (not illustrated), which may be disposed inside or outside of the main jig 110 and connected to the auxiliary vacuum generator 121 via a power line (not illustrated). The auxiliary vacuum generator 121 may include a vacuum pump or the like to generate vacuum pressure. The auxiliary vacuum generator 121 may be operated when the coating nozzle 130 supplies the coating solution to the cover member 210 and when the coating solution supplied to the cover member 210 is cured. The auxiliary vacuum generator 121 may be operated independently from the main vacuum generator 111.

The auxiliary adsorption portion 122 may be located on the auxiliary jig 120 and may adsorb the edge of the cover member 210 to the auxiliary jig 120. Inside the auxiliary jig 120, the auxiliary adsorption portion 122 may be disposed to be in contact with the upper surface of the auxiliary jig 120 and may be disposed directly beneath the edge of the cover member 210. The auxiliary adsorption portion 122 may adsorb the edge of the cover member 210 using vacuum pressure from the auxiliary vacuum generator 121.

The auxiliary connection portion 123 may connect the auxiliary vacuum generator 121 inside of the main jig 110 and the auxiliary adsorption portion 122 inside the auxiliary jig 120 to each other. The auxiliary connection portion 123 may provide a pathway through which vacuum pressure generated from the auxiliary vacuum generator 121 is applied to the auxiliary adsorption portion 122.

A plurality of auxiliary suction hole 124 may be provided, and the plurality of auxiliary suction hole 124 may be arranged along the first direction D1 and the second direction D2 on the upper surface of the auxiliary adsorption portion 122. The plurality of auxiliary suction hole 124 may be formed to penetrate the upper surface of the auxiliary jig 120 so that vacuum pressure applied to the auxiliary adsorption portion 122 may act directly on the edge of the cover member 210. In other words, a suction force may be generated from the plurality of auxiliary suction holes 124 to cause the edge of the cover member 210 to be adsorbed by the auxiliary adsorption portion 122.

Hereinafter, a coating method of a display device according to an embodiment of the present invention will be described with reference to the drawings.

The coating method of a display device according to an embodiment of the present invention may include placing a panel lower member 260 of the display device 200 on a main jig 110 and placing an edge of a cover member 210 of the display device 200 on an auxiliary jig 120, adsorbing the panel lower member 260 using the main jig 110 and adsorbing the edge of the cover member 210 using the auxiliary jig 120, supplying a coating solution to the upper surface of the cover member 210 using a coating nozzle 130, forming a coating layer 220 by curing the coating solution supplied to the upper surface of the cover member 210, and cutting the edge of the cover member 210 by a laser cutter 140.

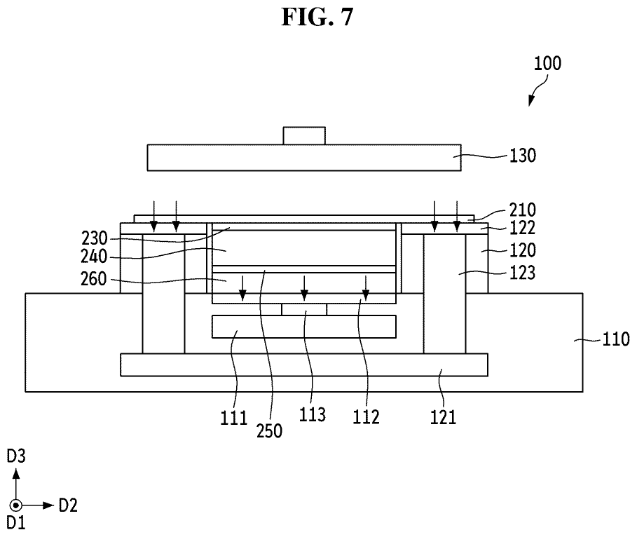

FIG. 7 is a diagram illustrating a state where a display device is mounted on a main jig and an auxiliary jig in a coating method of a display device according to an embodiment of the present disclosure.

Referring to FIG. 7, in mounting the panel lower member 260 of the display device 200 mounted on the main jig 110 and mounting the edge of the cover member 210 of the display device 200 mounted on the auxiliary jig 120, the panel lower member 260 may be secured to the main jig 110 so that the lower surface of the panel lower member 260 is in contact with a plurality of main suction holes 114 of the main adsorption portion 112. In addition, the edge of the cover member 210 may be mounted on the auxiliary jig 120 so that the lower surface of the edge of the cover member 210 is in contact with a plurality of auxiliary suction holes 124 of the auxiliary adsorption portion 122.

In the adsorbing the panel lower member 260 using the main jig 110 and adsorbing the edge of the cover member 210 using the auxiliary jig 120, the main vacuum generator 111 may be operated to apply vacuum pressure to the main adsorption portion 112, and the vacuum pressure applied to the main adsorption portion 112 may generate the suction force through the plurality of main suction holes 114 so that the panel lower member 260 can be adsorbed onto the main adsorption portion 112. In addition, the auxiliary vacuum generator 121 may be operated to apply vacuum pressure to the auxiliary adsorption portion 122, and the vacuum pressure applied to the auxiliary adsorption portion 122 may generate the suction force through the plurality of auxiliary suction holes 124 so that the edge of the cover member 210 can be adsorbed onto the auxiliary adsorption portion 122.

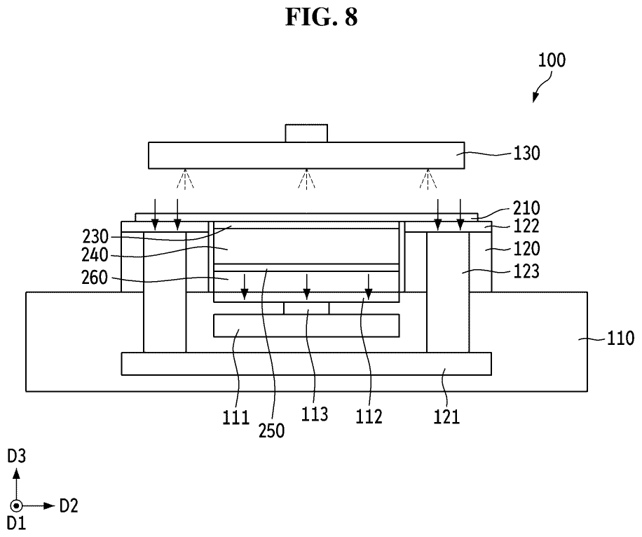

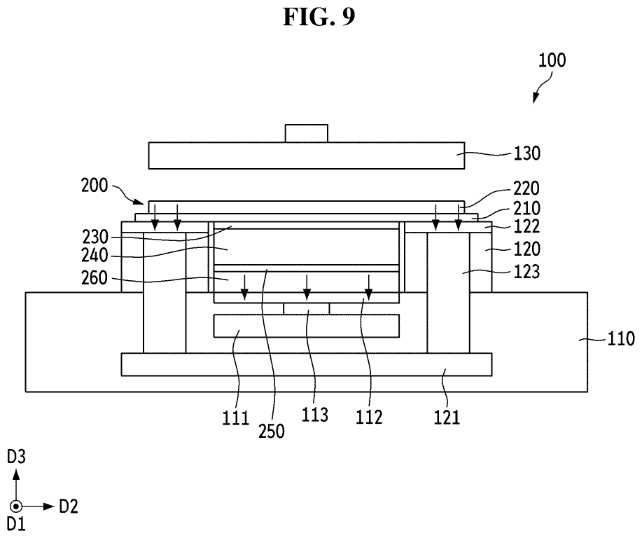

FIG. 8 is a diagram illustrating a state where coating solution is supplied from a coating nozzle to a cover member of a display device, in a state shown in FIG. 7. FIG. 9 is a diagram illustrating a state where the coating solution is supplied to the upper surface of the cover member.

Referring to FIGS. 8 and 9, in supplying the coating solution to the upper surface of the cover member 210 using a coating nozzle 130, the coating nozzle 130 may move in the first direction D1 and supply the coating solution to the upper surface of the cover member 210. As the coating nozzle 130 moves in the first direction D1, the coating solution may be supplied to the entire upper surface of the cover member 210. The coating solution supplied to the upper surface of the cover member 210 may form a coating layer 220.

When supplying the coating solution to the upper surface of the cover member 210 using the coating nozzle 130, the main vacuum generator 111 and the auxiliary vacuum generator 121 may be operated simultaneously to sustain the adsorption of the panel lower member 260 onto the main adsorption portion 112 and the adsorption of the edge of the cover member 210 onto the auxiliary adsorption portion 122. As described above, the edges of the panel lower member 260 and the cover member 210 are adsorbed and secured to the main jig 110 and the auxiliary jig 120 respectively, during the process of supplying coating solution to the upper surface of the cover member 210 by the coating nozzle 130, so that the coating solution supplied from the coating nozzle 130 may be evenly supplied to the upper surface of the cover member 210.

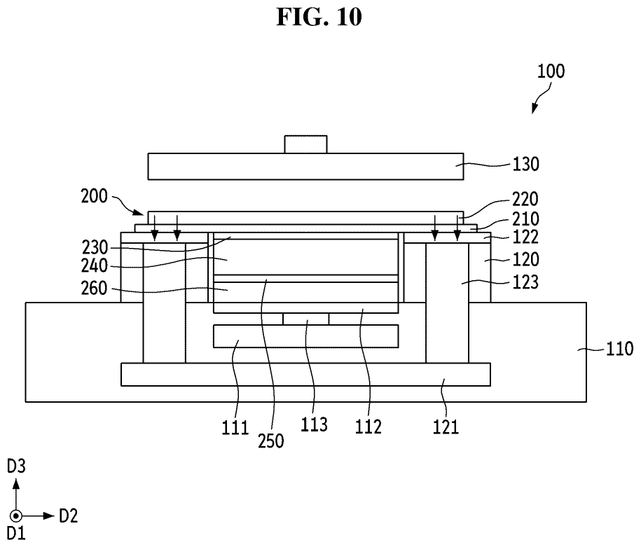

FIG. 10 is a diagram illustrating a state where the coating solution supplied to the cover member is being cured.

Referring to FIG. 10, in forming the coating layer 220 by curing the coating solution supplied to the upper surface of the cover member 210, the auxiliary vacuum generator 121 may be operated to sustain the adsorption of the edge of the cover member 210 onto the auxiliary adsorption portion 122. In contrast, during a process of forming the coating layer 220 by curing the coating solution supplied to the upper surface of the cover member 210, the main vacuum generator 111 may not be operated and the panel lower member 260 may not remain to be adsorbed by the main adsorption portion 112. If the panel lower member 260 is adsorbed onto the main adsorption portion 112 during the curing process of the coating layer 220, a suction force in the third direction D3 may be applied to the cover member 210, which is positioned above the panel lower member 260, and may leave a press mark in the coating layer 220 in the third direction D3. Accordingly, during the curing process of the coating layer 220, the main vacuum generator 111 may not be operated.

In curing of the coating layer 220, as the edge of the cover member 210 remains adsorbed onto the auxiliary adsorption portion 122, the cover member 210 remains in a taut condition, which may prevent the coating layer 220 from bending that may occur in the process of curing the coating layer 220. As the bending of the coating layer 220 is prevented, the surface quality of the coating layer 220 may be improved.

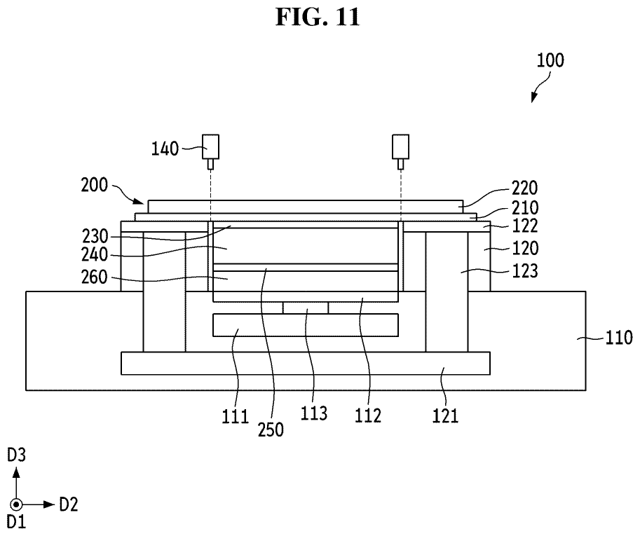

FIG. 11 is a diagram illustrating a state where a laser cutter cuts an edge of the cover member, in a state shown in FIG. 10.

Referring to FIG. 11, in cutting the edge of the cover member 210 by the laser cutter 140, the laser cutter 140 may irradiate the laser to cut the edge of the cover member 210. The laser cutter 140 may remove the edge of the cover member 210 by irradiating the laser into a gap space between the display panel 240 and the panel lower member 260 and the plurality of auxiliary jigs 120.

The display device 200 including the coating layer 220 manufactured using the coating device 100 according to an embodiment may be applied to a variety of electronic devices.

An electronic device according to an embodiment includes the above-described display device and may further include modules or devices having other additional functions, in addition to the display device.

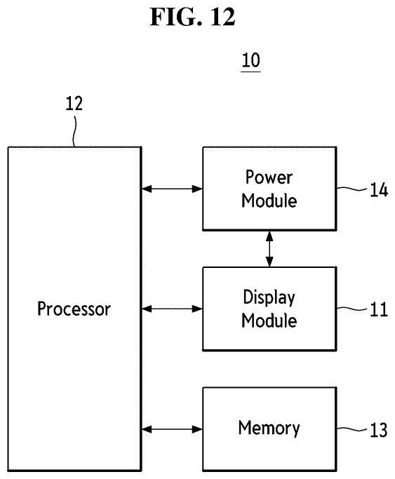

FIG. 12 is a block diagram of an electronic device according to an embodiment.

Referring to FIG. 12, an electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

Data information necessary for an operation of the processor 12 or the display module 11 may be stored in the memory 13. When the processor 12 executes an application stored in the memory 13, image data signals and/or input control signals may be transmitted to the display module 11, and the display module 11 may process the provided signals and output image information through a display screen.

The power module 14 may include a power supply module, such as a power adapter or a battery device, and a power conversion module that converts power supplied by the power supply module to generate power required for an operation of the electronic device 10.

At least one of the components of the electronic device 1 described above may be included in the display device according to the above-described embodiments. In addition, some of the individual modules functionally included within one module may be included within the display device, while others may be provided separately from the display device. For example, the display device includes the display module 11, and the processor 12, the memory 13, and the power module 14 may be provided in the form of other devices within the electronic device 1 other than the display device.

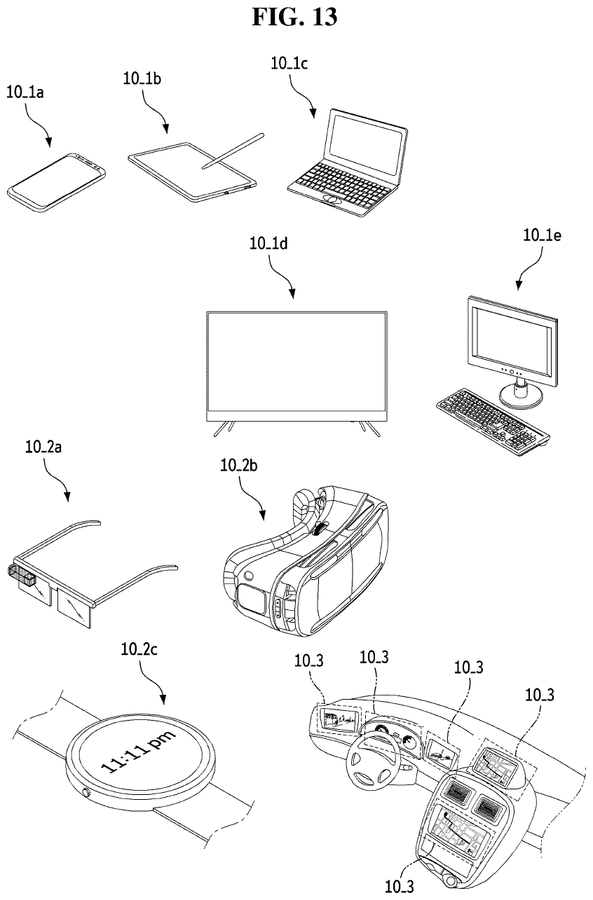

FIG. 13 are schematic diagrams of electronic devices according to various embodiments.

Referring to FIG. 13, various electronic devices to which the display device according to the embodiments is applied may include not only an image display electronic device such as a smart phone 10_1a, a tablet PC 10_1b, a laptop 10_1c, a TV 10_1d, and a desk monitor 10_1e, but also a wearable electronic device including a display module such as a smart glasses 10_2a, a head mounted display 10_2b, a smart watch 10_2c, and the like. The various electronic devices may include a vehicle electronic device 10_3 including a display module such as a Center Information Display (CID), a room mirror display, etc., arranged on a vehicle's instrument panel, center fascia, or dashboard.

It should be understood, however, that the aspects and features of embodiments of the present disclosure are not restricted to the embodiments set forth in this description. The above and other aspects of the present disclosure will become more apparent to one of ordinary skill in the art to which the present disclosure pertains by referencing the claims, with equivalents thereof to be included therein.

What is claimed is:

1. A coating device comprising:
a main jig supporting a display device;
an auxiliary jig located on the main jig and extending from an upper surface of the main jig, and supporting an edge of the display device; and
a coating nozzle supplying a coating solution to the display device.

2. The coating device of claim 1,
wherein the display device comprises:
a display panel;
a panel lower member located under the display panel; and
a cover member located on the display panel, and having a wider width than the display panel,
wherein the panel lower member is supported by the main jig, and an edge of the cover member is supported by the auxiliary jig.

3. The coating device of claim 2,
wherein the coating nozzle supplies the coating solution to an upper surface of the cover member.

4. The coating device of claim 2,
wherein the auxiliary jig is provided in plural forms, and
the plurality of auxiliary jigs are arranged to surround the display panel and the panel lower member.

5. The coating device of claim 4,
wherein the plurality of auxiliary jigs are arranged to be spaced apart from the display panel and the panel lower member along a first direction.

6. The coating device of claim 4,
wherein the plurality of auxiliary jigs are formed to extend outside the edge of the cover member so that an entire edge of the cover member is supported by the plurality of auxiliary jigs.

7. The coating device of claim 2, further comprising:
a main adsorption portion located in the main jig, and adsorbing the panel lower member onto the main jig;
a main vacuum generator applying a first vacuum pressure to the main adsorption portion;
an auxiliary adsorption portion located in the auxiliary jig, and adsorbing the edge of the cover member onto the auxiliary jig; and
an auxiliary vacuum generator applying a second vacuum pressure to the auxiliary adsorption portion.

8. The coating device of claim 7,
wherein a plurality of main suction holes are formed in an upper surface of the main adsorption portion in contact with the panel lower member, and
a plurality of auxiliary suction holes are formed in an upper surface of the auxiliary adsorption portion in contact with the edge of the cover member.

9. The coating device of claim 7, further comprising:
a main connecting portion connecting the main adsorption portion to the main vacuum generator; and
an auxiliary connecting portion connecting the auxiliary adsorption portion to the auxiliary vacuum generator.

10. The coating device of claim 7,
wherein the main vacuum generator and the auxiliary vacuum generator are located inside the main jig, and
the main vacuum generator and the auxiliary vacuum generator are operated independently from each other.

11. The coating device of claim 7,
wherein, when the coating nozzle supplies the coating solution to the cover member, the main vacuum generator and the auxiliary vacuum generator are operated simultaneously, and
when the coating solution supplied to the cover member is cured, only the auxiliary vacuum generator is operated.

12. A coating method of a display device, the coating method comprising:
placing a panel lower member of a display device on a main jig and placing an edge of a cover member of the display device to an auxiliary jig;
adsorbing the panel lower member using the main jig and adsorbing the edge of the cover member using the auxiliary jig;
supplying a coating solution to an upper surface of the cover member through a coating nozzle; and
forming a coating layer by curing the coating solution supplied to the upper surface of the cover member.

13. The coating method of claim 12,
wherein the auxiliary jig includes an auxiliary adsorption portion adsorbing the edge of the cover member, and
the main jig includes a main adsorption portion adsorbing the panel lower member, a main vacuum generator applying a first vacuum pressure to the main adsorption portion, and an auxiliary vacuum generator applying a second vacuum pressure to the auxiliary adsorption portion.

14. The coating method of claim 13,
wherein, in the process of adsorbing the panel lower member using the main jig and adsorbing the edge of the cover member using the auxiliary jig, the main vacuum generator applies the first vacuum pressure to the main adsorption portion to adsorb the panel lower member by the main adsorption portion, and the auxiliary vacuum generator applies the second vacuum pressure to the auxiliary adsorption portion to adsorb the edge of the cover member by the auxiliary adsorption portion.

15. The coating method of claim 14,
wherein, in the process of supplying the coating solution to the upper surface of the cover member by the coating nozzle, the main adsorption portion adsorbs the panel lower member and the auxiliary adsorption portion adsorbs the edge of the cover member.

16. The coating method of claim 13,
wherein, in the process of forming the coating layer by curing the coating solution supplied to the upper surface of the cover member, the auxiliary vacuum generator is operated so that the auxiliary adsorption portions adsorbs the edge of the cover.

17. The coating method of claim 12, further comprising:
cutting the edge of the cover member by a laser cutter.

18. An electronic device comprising a display device manufactured using a coating
device,
wherein the coating device comprises:
a main jig supporting a panel lower member of the display device;
an auxiliary jig located on the main jig and extending from an upper surface of the main jig, and supporting an edge of a cover member of the display device; and
a coating nozzle supplying a coating solution to the cover member of the display device.

19. The electronic device of claim 18, further comprising:
a main adsorption portion located in the main jig, and adsorbing the panel lower member onto the main jig;
a main vacuum generator applying a first vacuum pressure to the main adsorption portion;
an auxiliary adsorption portion located in the auxiliary jig, and adsorbing the edge of the cover member onto the auxiliary jig; and
an auxiliary vacuum generator applying a second vacuum pressure to the auxiliary adsorption portion.

20. The electronic device of claim 19,
wherein, when the coating nozzle supplies the coating solution to the cover member, the main vacuum generator and the auxiliary vacuum generator are operated simultaneously, and
when the coating solution supplied to the cover member is cured, only the auxiliary vacuum generator is operated.
